(19) United States
(12) Patent Application Publication
(10) Pub. No.: US 2026/0221711 A1
(43) Pub. Date: Jul. 30, 2026

(54) EXCIMER LASER APPARATUS AND ELECTRONIC DEVICE MANUFACTURING METHOD

(71) Applicant: Gigaphoton Inc., Tochigi (JP)

(72) Inventor: Yousuke KAWAGOE, Tochigi (JP)

(73) Assignee: Gigaphoton Inc., Tochigi (JP)

(21) Appl. No.: 19/410,661

(22) Filed: Dec. 5, 2025

(30) Foreign Application Priority Data
Jan. 28, 2025 (JP) 2025-011814

(51) Int. Cl. H01S 3/097; G03F 7/00; H01S 3/225

(52) U.S. Cl. CPC H01S 3/09702; G03F 7/70025; G03F 7/70041; G03F 7/70508; G03F 7/7055; G03F 7/7085; H01S 3/225

(57) ABSTRACT

An excimer laser apparatus includes an optical resonator, a chamber that includes a pair of electrodes and is disposed in an optical path of the optical resonator, a pulse power module configured to apply a pulse voltage between the electrodes, a charger configured to store electric energy to be supplied to the pulse power module, an energy monitor configured to measure pulse energy of a pulse laser beam output from the optical resonator, and a processor configured to acquire a charging voltage command value of the charger and a measured value of the pulse energy for each of a plurality of pulses, to obtain a correlation between the charging voltage command value and the pulse energy, and to determine whether or not the measured value is outside an allowable range based on a calculated value of the pulse energy calculated from the charging voltage command value and the correlation.

### CROSS-REFERENCE TO RELATED APPLICATIONS

The present application claims the benefit of Japanese Patent Application No. 2025-011814, filed on Jan. 28, 2025, the entire contents of which are hereby incorporated by reference.

### BACKGROUND

### 1. Technical Field

The present disclosure relates to an excimer laser apparatus and an electronic device manufacturing method.

### 2. Related Art

Recently, in a semiconductor exposure apparatus, improvement in resolution has been desired for miniaturization and high integration of semiconductor integrated circuits. For this purpose, exposure light sources that output light having a shorter wavelength have been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

In addition, excimer laser beams output from KrF and ArF excimer laser apparatuses are sometimes used for direct processing of a polymer material and a glass material or the like, since a pulse width is several tens of ns and a wavelength is as short as about 248 nm and about 193 nm, respectively. A chemical bond in a polymer material can be cut by an excimer laser beam having photon energy higher than bond energy. Therefore, it is known that non-heating processing of a polymer material is made possible by an excimer laser beam, and a processing shape becomes smooth. Further, since glass, ceramics, and the like have a high absorptance to an excimer laser beam, it is known that even a material that is difficult to be processed by visible and infrared laser beams can be processed by an excimer laser beam.

### LIST OF DOCUMENTS

### Patent Documents

Patent Document 1: US Patent Application Publication No. 2018/0261973
Patent Document 2: US Patent Application Publication No. 2019/0134748

### SUMMARY

An excimer laser apparatus according to one aspect of the present disclosure includes an optical resonator, a chamber, a pulse power module, a charger, an energy monitor, and a processor. The chamber includes a pair of electrodes and is disposed in an optical path of the optical resonator. The pulse power module is configured to apply a pulse voltage between the electrodes. The charger is configured to store electric energy to be supplied to the pulse power module. The energy monitor is configured to measure pulse energy of a pulse laser beam output from the optical resonator. The processor is configured to acquire a charging voltage command value of the charger and a measured value of the pulse energy for each of a plurality of pulses, to obtain a correlation between the charging voltage command value and the pulse energy, and to determine whether or not the measured value is outside an allowable range based on a calculated value of the pulse energy calculated from the charging voltage command value and the correlation.

An electronic device manufacturing method according to one aspect of the present disclosure includes generating a pulse laser beam with an excimer laser apparatus, outputting the pulse laser beam to an exposure apparatus, and exposing a photosensitive substrate to the pulse laser beam in the exposure apparatus to manufacture an electronic device. The excimer laser apparatus includes an optical resonator, a chamber that includes a pair of electrodes and is disposed in an optical path of the optical resonator, a pulse power module configured to apply a pulse voltage between the electrodes, a charger configured to store electric energy to be supplied to the pulse power module, an energy monitor configured to measure pulse energy of the pulse laser beam output from the optical resonator, and a processor configured to acquire a charging voltage command value of the charger and a measured value of the pulse energy for each of a plurality of pulses, to obtain a correlation between the charging voltage command value and the pulse energy, and to determine whether or not the measured value is outside an allowable range based on a calculated value of the pulse energy calculated from the charging voltage command value and the correlation.

### BRIEF DESCRIPTION OF THE DRAWINGS

Some embodiments of the present disclosure will be described below, by way of example only, with reference to the accompanying drawings.

FIG. 1 illustrates a configuration of an exposure system in a comparative example.

FIG. 2 illustrates an example of a semiconductor wafer exposed by the exposure system.

FIG. 3 illustrates an example of a trigger signal transmitted to a pulse power module.

FIG. 4 is a flowchart illustrating pulse energy control by a laser control processor of an excimer laser apparatus according to the comparative example.

FIG. 5 is a diagram explaining a mechanism estimated for occurrence of an energy drop, illustrating a normal case where the energy drop is unlikely to occur.

FIG. 6 is a diagram explaining a mechanism estimated for occurrence of an energy drop, illustrating a case where the energy drop is likely to occur.

FIG. 7 is a frequency distribution diagram explaining a method of detecting an energy drop in the comparative example.

FIG. 8 is an energy distribution diagram illustrating a relationship between a voltage command value and a measured value of pulse energy.

FIG. 9 is a frequency distribution diagram corresponding to FIG. 8.

FIG. 10 is an energy distribution diagram explaining a method of detecting an energy drop in an embodiment.

FIG. 11 is a flowchart of data acquisition for detecting an energy drop in the embodiment.

FIG. 12 is a flowchart of parameter control performed based on data acquired in the embodiment.

FIG. 13 illustrates a configuration of the exposure system.

### DESCRIPTION OF EMBODIMENTS

### <Contents>

1. Comparative Example
   1.1 Exposure System
   1.2 Excimer Laser Apparatus 1
      1.2.1 Configuration
      1.2.2 Operation
   1.3 Burst Oscillation
   1.4 Pulse Energy Control
   1.5 Occurrence of Energy Drop
   1.6 Detection of Energy Drop
   1.7 Problem of Comparative Example
2. Excimer Laser Apparatus 1 that Sets Allowable Range of Measured value Eᵢ from Correlation between Charging Voltage Command Value Vᵢ and Measured Value Eᵢ of Pulse Energy
   2.1 Operation
   2.2 Effect
3. Others
   3.1 Laser Control Processor 30
   3.2 Electronic Device Manufacturing Method
   3.3 Supplement

Embodiments of the present disclosure will be described below in detail with reference to the accompanying drawings. The embodiments described below show some examples of the present disclosure and do not limit the content of the present disclosure. Not all configurations and operations described in each embodiment are necessarily essential as configurations and operations of the present disclosure. Here, the same components are denoted by the same reference signs, and any redundant description thereof is omitted.

### 1. Comparative Example

### 1.1 Exposure System

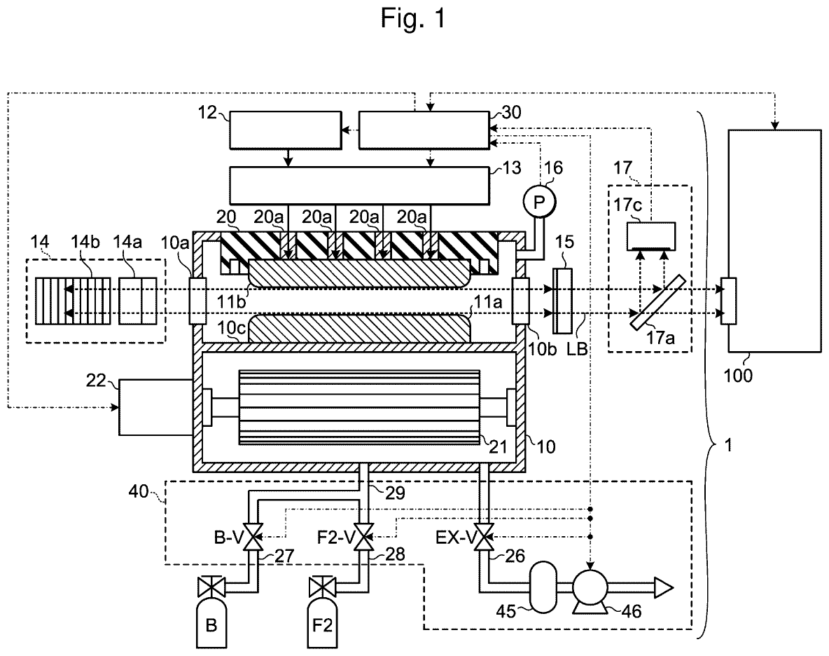

FIG. 1 illustrates a configuration of the exposure system in the comparative example. The comparative example of the present disclosure is an example recognized by the applicant as known only by the applicant, and is not a publicly known example admitted by the applicant. The exposure system includes an excimer laser apparatus 1 and an exposure apparatus 100. The exposure apparatus 100 includes a non-illustrated exposure control processor. The exposure control processor is configured to transmit setting data of target pulse energy Et and to transmit a light emission trigger signal to a laser control processor 30 included in the excimer laser apparatus 1.

### 1.2 Excimer Laser Apparatus 1

### 1.2.1 Configuration

The excimer laser apparatus 1 includes a chamber 10, a charger 12, a pulse power module 13, a line narrowing module 14, an output coupling mirror 15, a chamber pressure sensor 16, an energy monitor 17, the laser control processor 30, and a gas supply and exhaust device 40. The line narrowing module 14 and the output coupling mirror 15 form an optical resonator. The chamber 10 includes windows 10a and 10b, a pair of electrodes 11a and 11b, and a cross-flow fan 21. The chamber 10 is disposed such that the windows 10a and 10b are positioned in an optical path of the optical resonator. The laser control processor 30, which corresponds to a processor in the present disclosure, will be described later.

The line narrowing module 14 includes a prism 14a and a grating 14b. The prism 14a is disposed in an optical path of light output through the window 10a. The grating 14b is disposed in an optical path of the light having transmitted through the prism 14a. The output coupling mirror 15 is formed of a partial reflective mirror.

The chamber 10 is filled with a laser gas containing, for example, an argon gas or a krypton gas as a rare gas, a fluorine gas as a halogen gas, and a neon gas as a buffer gas, or the like. Alternatively, a laser gas containing a fluorine gas and a buffer gas may be enclosed.

An opening is formed in a part of the chamber 10, and this opening is closed by an electrically insulating part 20. A plurality of conductive parts 20a are embedded in the electrically insulating part 20. The pulse power module 13 is connected to the electrode 11b via each of the conductive parts 20a.

A return plate 10c is disposed inside the chamber 10. The electrode 11a is supported by the return plate 10c. The electrode 11a is electrically connected to ground potential via the return plate 10c and non-illustrated wiring. The return plate 10c has a gap for the laser gas to pass through, on a back side and a front side of a plane of FIG. 1.

The chamber pressure sensor 16 is configured to measure a pressure of the laser gas in the chamber 10 and to output a measurement result to the laser control processor 30. The pressure of the laser gas measured by the chamber pressure sensor 16 is a total pressure of the laser gas.

The energy monitor 17 includes a beam splitter 17a and a photosensor 17c. The beam splitter 17a is disposed in an optical path of a pulse laser beam LB output from the output coupling mirror 15. The beam splitter 17a transmits a portion of the pulse laser beam LB toward the exposure apparatus 100 at a high transmittance, while reflecting the other portion toward the photosensor 17c. The photosensor 17c is, for example, a photodiode sensitive to ultraviolet light such as the pulse laser beam LB. The photosensor 17c measures pulse energy of the pulse laser beam LB reflected by the beam splitter 17a and transmits a measurement result to the laser control processor 30.

The cross-flow fan 21 has its rotating shaft connected to a motor 22. By rotating the cross-flow fan 21 with the motor 22, the laser gas is circulated inside the chamber 10.

The gas supply and exhaust device 40 includes a gas supply device and an exhaust device. As the gas supply device, the gas supply and exhaust device 40 includes pipes 27 to 29 and valves B-V and F2-V.

The pipe 28 is connected to a halogen-containing gas supply source F2. The pipe 29 is connected to the chamber 10. The halogen-containing gas supply source F2 is, for example, a gas cylinder holding a halogen-containing gas obtained by mixing a fluorine gas, an argon gas, and a neon gas. The valve F2-V is provided in the pipe 28 and controls supply of the halogen-containing gas to the chamber 10.

The pipe 27 is connected between a buffer gas supply source B and the pipe 29. The buffer gas supply source B is, for example, a gas cylinder holding a buffer gas that contains an argon gas and a neon gas. The valve B-V is provided in the pipe 27 and controls the supply of the buffer gas to the chamber 10.

As the exhaust device, the gas supply and exhaust device 40 includes a pipe 26, a valve EX-V, a halogen gas trap 45, and an exhaust pump 46. The pipe 26 is connected between the chamber 10 and a non-illustrated exhaust processing device or the like outside the device. The valve EX-V, the halogen gas trap 45, and the exhaust pump 46 are disposed in the pipe 26 in this order from a side of the chamber 10. The valve EX-V controls the supply of an exhaust gas from the chamber 10 to the halogen gas trap 45. The halogen gas trap 45 captures the halogen gas contained in the laser gas exhausted from the chamber 10. The exhaust pump 46 forcibly exhausts the laser gas in the chamber 10 to a pressure lower than or equal to an atmospheric pressure in a state where the valve EX-V is open.

### 1.2.2 Operation

Upon receiving the setting data of the target pulse energy Et from the exposure control processor of the exposure apparatus 100, the laser control processor 30 transmits a charging voltage command value Vᵢ to the charger 12. Upon receiving the light emission trigger signal from the exposure control processor, the laser control processor 30 transmits the trigger signal to the pulse power module 13.

Upon receiving a trigger signal from the laser control processor 30, the pulse power module 13 generates a pulsed high voltage from electric energy stored in the charger 12 and applies this high voltage between the electrodes 11a and 11b.

When the pulse power module 13 applies the high voltage between the electrodes 11a and 11b, discharge occurs between the electrodes 11a and 11b. By energy of the discharge, a laser medium in the chamber 10 is excited and shifts to a high energy level. When the excited laser gas shifts to a low energy level thereafter, light having a wavelength in accordance with the energy level difference is discharged.

The light generated in a discharge space between the electrodes 11a and 11b is output to an outside of the chamber 10 through the windows 10a and 10b. A beam width of the light output from the window 10a is expanded by the prism 14a and the light is incident on the grating 14b. The light incident on the grating 14b is reflected by a plurality of grooves of the grating 14b and is diffracted in a direction in accordance with the wavelength of the light. The grating 14b is disposed in Littrow arrangement such that an incident angle of the light incident on the grating 14b from the prism 14a coincides with a diffracting angle of diffracted light having a desired wavelength. Accordingly, light having a wavelength near the desired wavelength is returned to the chamber 10 through the prism 14a.

The output coupling mirror 15 transmits and outputs part of the light output through the window 10b and reflects the other part back into the chamber 10.

In this way, the light generated in the discharge space reciprocates between the line narrowing module 14 and the output coupling mirror 15. This light is amplified each time it passes through the discharge space and is subjected to line narrowing each time it is returned from the line narrowing module 14. The light that is amplified and line-narrowed in this way and is subjected to laser oscillation is output as the pulse laser beam LB from the output coupling mirror 15 and is incident on the exposure apparatus 100.

### 1.3 Burst Oscillation

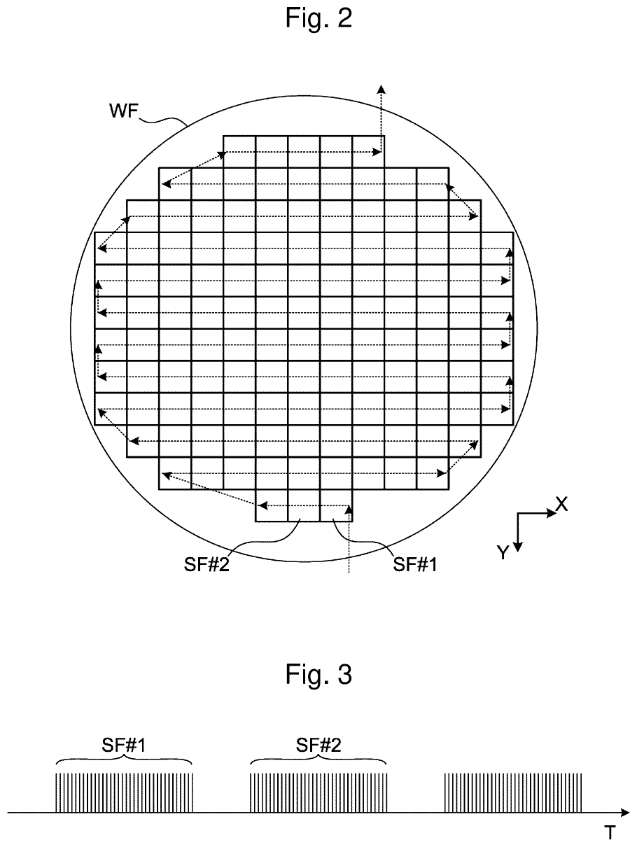

FIG. 2 illustrates an example of a semiconductor wafer WF exposed by the exposure system. FIG. 2 illustrates an X axis and a Y axis that are orthogonal to each other in a plane of the semiconductor wafer WF. The semiconductor wafer WF is, for example, a single crystal silicon plate having a substantially disk shape. The semiconductor wafer WF is coated with a photosensitive resist film, for example. The semiconductor wafer WF is exposed for each section of scan fields SF #1, SF #2, and others. Each of the scan fields SF #1 and SF #2 corresponds to a region where a reticle pattern of a single reticle is transferred. #1 and #2 indicate exposure orders. When descriptions are given without specifying the exposure order, #1, #2, and others may not be added. The semiconductor wafer WF is moved such that the first scan field SF #1 is irradiated with the pulse laser beam LB, and the scan field SF #1 is exposed. Then, the semiconductor wafer WF is moved such that the second scan field SF #2 is irradiated with the pulse laser beam LB, and the scan field SF #2 is exposed. Thereafter, all the scan fields SF are exposed while moving the semiconductor wafer WF in a same manner.

FIG. 3 illustrates an example of a trigger signal transmitted to the pulse power module 13. When one scan field SF is exposed, the pulse laser beam LB is continuously output at a predetermined repetition frequency. When moving from one scan field SF to another scan field SF, output of the pulse laser beam LB is stopped. An operation of continuously outputting the pulse laser beam LB is called burst oscillation. In order to expose a single semiconductor wafer WF, the burst oscillation and an oscillation stop are alternately performed.

### 1.4 Pulse Energy Control

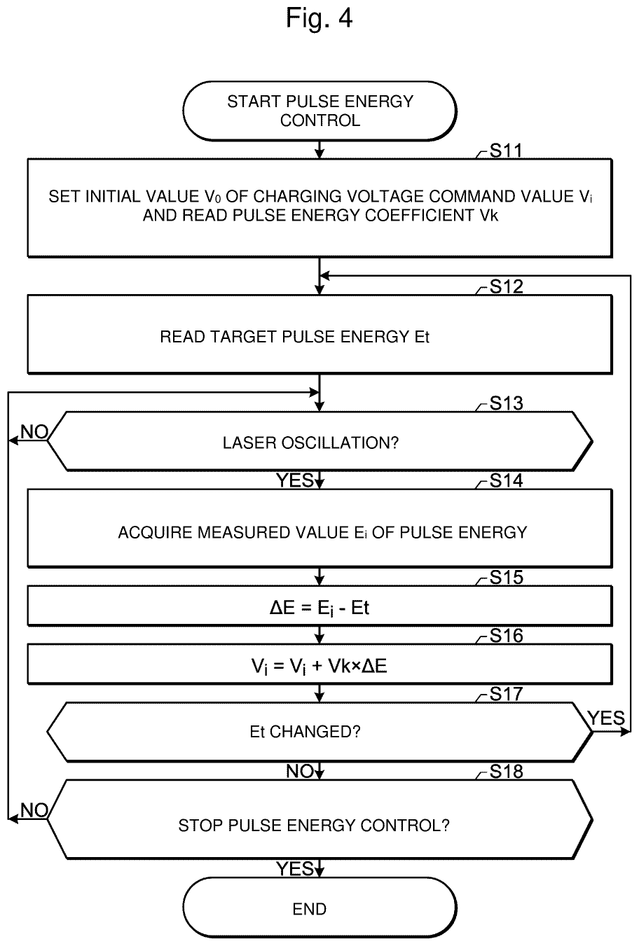

FIG. 4 is a flowchart illustrating pulse energy control by the laser control processor 30 of the excimer laser apparatus 1 according to the comparative example. The laser control processor 30 controls a measured value E of the pulse energy of the pulse laser beam LB to approach the target pulse energy Et through processing below.

In S11, the laser control processor 30 sets an initial value V₀ of the charging voltage command value V₁. In addition, the laser control processor 30 reads a pulse energy coefficient Vk from a non-illustrated memory. The pulse energy coefficient Vk is a coefficient used to calculate how much the charging voltage command value Vᵢ should be changed when the pulse energy is to be changed by ΔE (see S16).

In S12, the laser control processor 30 reads the target pulse energy Et from the memory. A value of the target pulse energy Et may be specified by the exposure apparatus 100.

In S13, the laser control processor 30 determines whether or not the laser oscillation has been performed. If the laser oscillation has not been performed, the laser control processor 30 waits until the laser oscillation is performed. If the laser oscillation has been performed, the laser control processor 30 advances the processing to S14.

In S14, the laser control processor 30 acquires the measured value Eᵢ of the pulse energy based on output of the energy monitor 17.

In S15, the laser control processor 30 calculates a difference ΔE between the measured value Eᵢ of the pulse energy and the target pulse energy Et using an equation below.

$$Δ E = {E}_{i} - E t$$

In S16, the laser control processor 30 calculates a new charging voltage command value Vᵢ based on the current charging voltage command value Vᵢ using an equation below, and updates the value of the charging voltage command value V₁.

$${V}_{i} = {V}_{i} + Vk \times Δ E$$

In S17, the laser control processor 30 determines whether or not the target pulse energy Et has been changed. If the target pulse energy Et has been changed, the laser control processor 30 returns the processing to S12. If the target pulse energy Et has not been changed, the processing is advanced to S18.

In S18, the laser control processor 30 determines whether or not to stop the pulse energy control. If the pulse energy control is not to be stopped, the laser control processor 30 returns the processing to S13. If the pulse energy control is to be stopped, the laser control processor 30 ends the processing of the present flowchart.

In addition to the control illustrated in FIG. 4, the total pressure of the laser gas inside the chamber 10 may be controlled according to the charging voltage command value Vᵢ. The control of the total pressure includes raising the total pressure when the charging voltage command value Vᵢ becomes larger than a threshold Vᵢmax, so as to obtain the measured value Eᵢ of the pulse energy close to the target pulse energy Et with a low charging voltage command value Vᵢ. The control of raising the total pressure includes controlling the gas supply device of the gas supply and exhaust device 40.

In addition, the control of the total pressure includes lowering the total pressure when the charging voltage command value Vᵢ becomes smaller than a threshold Vᵢmin, which is smaller than the threshold Vᵢmax, so as to obtain the measured value Eᵢ of the pulse energy close to the target pulse energy Et with a high charging voltage command value Vᵢ. The control of lowering the total pressure includes controlling the exhaust device of the gas supply and exhaust device 40.

### 1.5 Occurrence of Energy Drop

When the excimer laser apparatus 1 is operated for a long time and, for example, a pulse number of the output pulse laser beam LB reaches several tens of billions of pulses, the electrodes 11a and 11b may deteriorate. As a result, a phenomenon called an energy drop may occur. That is, while most of the pulses of the pulse laser beam LB have the pulse energy close to the target pulse energy Et, some pulses may only have the pulse energy significantly smaller compared to the target pulse energy Et. Thus, in the present description, the phenomenon where only the pulse energy smaller compared to the target pulse energy Et is produced is described as the energy drop.

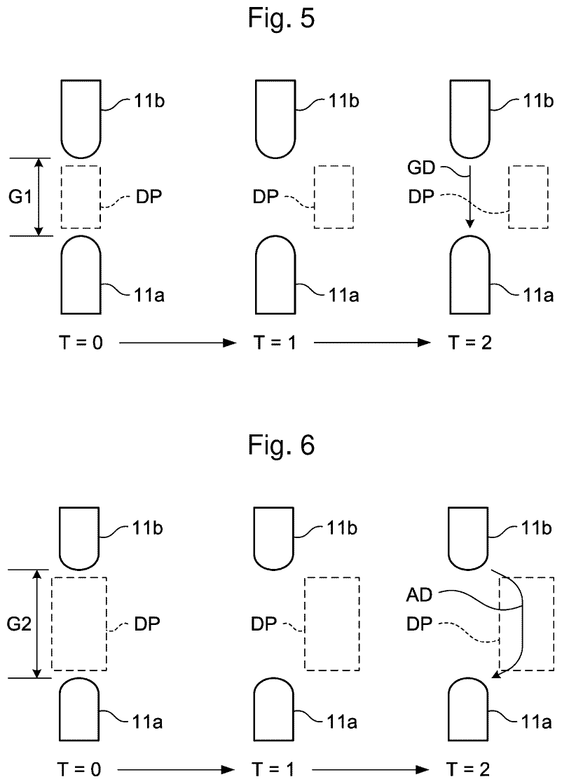

FIG. 5 and FIG. 6 are diagrams explaining a mechanism estimated for occurrence of the energy drop. FIG. 5 illustrates a normal case where deterioration of the electrodes 11a and 11b has not progressed and the energy drop is unlikely to occur. When the laser gas is excited in the discharge space between the electrodes 11a and 11b by the discharge between the electrodes 11a and 11b, discharge products DP are generated at a time T of 0. The discharge products DP include the laser gas in a plasma state. As described above, inside the chamber 10, the laser gas is circulated by the cross-flow fan 21. A direction of a gas flow of the laser gas is approximately perpendicular to both a discharge direction between the electrodes 11a and 11b and an output direction of the pulse laser beam LB. Such a gas flow causes the discharge products DP to move away from the electrodes 11a and 11b within a time T of 1, and the laser gas is supplied from an upstream side of the gas flow into the discharge space. Therefore, the next discharge that occurs at a time T of 2 becomes normal glow discharge GD, and the pulse laser beam LB with the pulse energy close to the target pulse energy Et is output.

FIG. 6 illustrates a case where the deterioration of the electrodes 11a and 11b has progressed and the energy drop is likely to occur. As the degradation of the electrodes 11a and 11b progresses, a gap G2 between the electrodes 11a and 11b becomes larger compared to a gap G1 in FIG. 5. In this case, the discharge at the time T of 2 may become arc discharge AD that passes through the discharge products DP generated in the previous discharge. It is estimated that reasons why a larger gap G2 leads to the arc discharge AD are the following two. First, as the gap G2 increases, not only does the discharge space in the discharge direction increase, but the discharge space also increases in the direction of the gas flow perpendicular to the discharge direction. Therefore, since the discharge products DP are distributed over a relatively wide range as illustrated at the times T of 0 and T of 1, the discharge products DP at the time T of 2 may not be sufficiently far from the electrodes 11a and 11b. Second, as the gap G2 increases, cross-sectional area of a flow path of the laser gas flowing between the electrodes 11a and 11b increases. Therefore, even if a rotational speed of the cross-flow fan 21 is constant, a flow rate of the laser gas decreases, and the discharge products DP at the time T of 2 may not be sufficiently far from the electrodes 11a and 11b. When the arc discharge AD occurs in such a manner, the laser gas located between the electrodes 11a and 11b may not be sufficiently excited, resulting in insufficient pulse energy of the pulse laser beam LB.

If such an energy drop occurs while exposure is being performed in the exposure apparatus 100, an exposure performance may be adversely affected. In order to reduce the occurrence of the energy drop, it is conceivable to replace the chamber 10, which includes the electrodes 11a and 11b, with a new one. However, to replace the chamber 10, it is necessary to temporarily stop the output of the pulse laser beam LB. If the output of the pulse laser beam LB is stopped to replace the chamber 10 when it is not a scheduled periodic maintenance time, a production schedule in a semiconductor factory may be affected and productivity may decrease.

### 1.6 Detection of Energy Drop

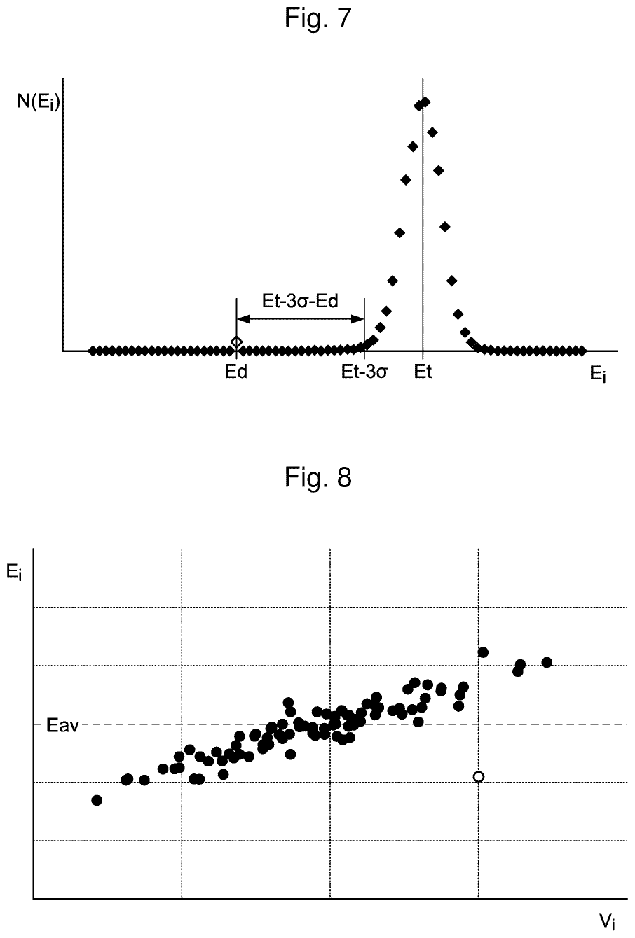

FIG. 7 is a frequency distribution diagram explaining a method of detecting an energy drop in the comparative example. In FIG. 7, a horizontal axis represents the pulse energy measured value Eᵢ, and a vertical axis represents a frequency N(Eᵢ) of each measured value Eᵢ, that is, the number of occurrences. The measured value Eᵢ is controlled to approach the target pulse energy Et, and a frequency distribution of the measured values Eᵢ illustrated in FIG. 7 has a steep peak near the target pulse energy Et. An average value Eav of the measured values Eᵢ is almost equal to the target pulse energy Et. In an ideal case where the degradation of the electrodes 11a and 11b has not progressed, a distribution of the measured values Eᵢ is nearly a normal distribution. When a standard deviation of the measured values Eᵢ is σ, a probability that the measured values Eᵢ fall within a range of ±3σ from the target pulse energy Et is about 99.73%.

As the degradation of the electrodes 11a and 11b progresses, an occurrence frequency of the energy drop, where the measured value Eᵢ becomes a value Ed that is significantly lower than the target pulse energy Et, may increase. The energy drop can be a larger problem when not only the frequency N(Eᵢ) but also a difference Et-3σ-Eᵢ between a value Et-3σ and the measured value Eᵢ is larger. Therefore, a value obtained by adding products of N(Eᵢ) and (Et-3σ-Eᵢ) within a predetermined range is defined as an energy drop index ED. The predetermined range is, for example, a range in which Eᵢ is from 0 to Eav-3σ. Specifically, it is expressed by an equation below.

$$E D = {\sum }_{{E}_{i} = 0}^{Eav - 3 σ} [ N ( {E}_{i} ) \cdot ( Et - 3 σ - {E}_{i} ) ] \qquad [ Expression 1 ]$$

When this energy drop index ED reaches a specified value, for example, a partial pressure of fluorine in the chamber 10 is adjusted. This suppresses the occurrence of the energy drop.

### 1.7 Problem of Comparative Example

The energy drop index ED in the comparative example is calculated considering only the measured values Eᵢ that are more than 3σ away from the average value Eav, which is a center of the frequency distribution of the measured values Eᵢ. However, in the comparative example, a relationship with the charging voltage command value Vᵢ is not considered. For example, in the comparative example, when the pulse energy measured value Eᵢ of a certain pulse is lower than the target pulse energy Et, the charging voltage command value Vᵢ for the next pulse is increased (see FIG. 4) to perform control of maintaining the measured value Eᵢ near the target pulse energy Et. Therefore, even if the target pulse energy Et is a constant value, the charging voltage command value Vᵢ is not necessarily a constant value.

FIG. 8 is an energy distribution diagram illustrating a relationship between the charging voltage command value Vᵢ and the measured value Eᵢ of the pulse energy. Each black circle represents one pulse. The pulse energy measured value Eᵢ of another pulse represented by a white circle may not be far from the average value Eav, but it may have a low value among the pulses with close charging voltage command values Vᵢ.

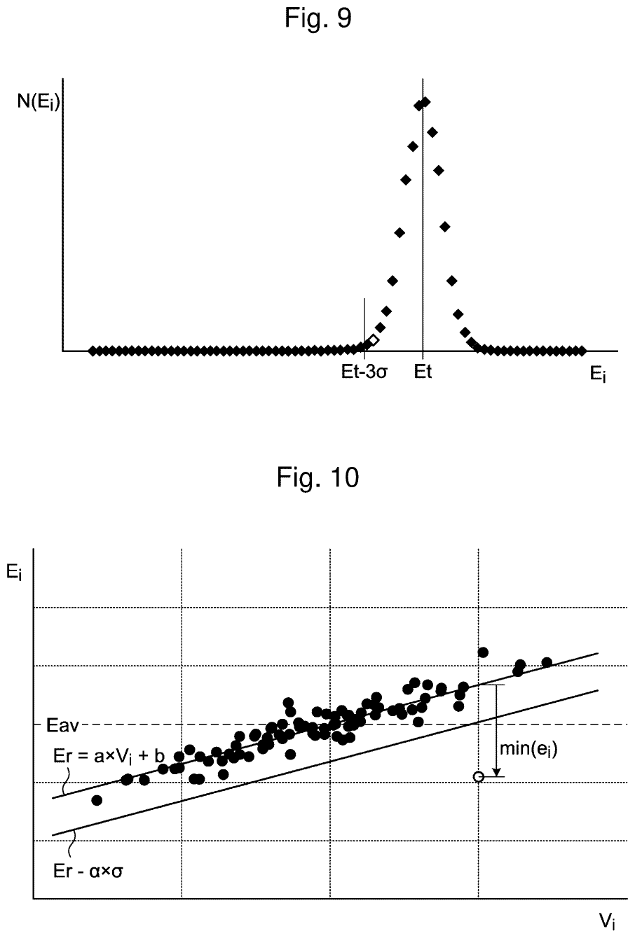

FIG. 9 is the frequency distribution diagram corresponding to FIG. 8. The pulse energy measured value Eᵢ of the pulse represented by the white circle in FIG. 8 corresponds to a position on the horizontal axis of a white square in FIG. 9.

For the pulse represented by the white circle illustrated in FIG. 8, the pulse energy measured value Et corresponding to the charging voltage command value Vᵢ has not been obtained, however, it cannot be detected as the energy drop in the comparative example. If a state where such a pulse represented by the white circle is generated continues, the degradation of the laser gas and the electrodes 11a and 11b is accelerated by the arc discharge AD, and energy stability may be deteriorated.

The embodiment described below relates to detecting pulse energy abnormalities due to discharge abnormalities or the like by detecting an energy drop considering a relationship between the charging voltage command value Vᵢ and the measured value Eᵢ of the pulse energy.

### 2. Excimer Laser Apparatus 1 that Sets Allowable Range of Measured Value Eᵢ from Correlation Between Charging Voltage Command Value Vᵢ and Measured Value Eᵢ of Pulse Energy

### 2.1 Operation

FIG. 10 is an energy distribution diagram explaining a method of detecting an energy drop in the embodiment. In FIG. 10, a regression line Er that satisfies a× Vᵢ+b and a line indicating an allowable range obtained by subtracting −α×σ from the regression line are added to the energy distribution diagram in FIG. 8.

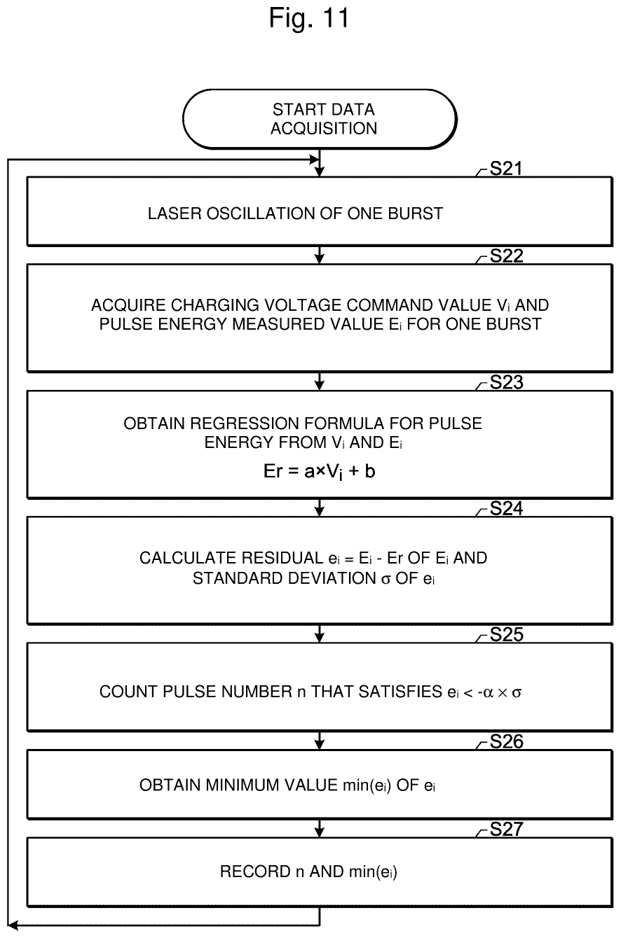

FIG. 11 is a flowchart of data acquisition for detecting an energy drop in the embodiment. A configuration of the embodiment is the same as the configuration of the comparative example described with reference to FIG. 1. The laser control processor 30 acquires data for each burst as follows.

In S21, the laser control processor 30 controls the excimer laser apparatus 1 so as to cause laser oscillation of one burst.

In S22, the laser control processor 30 acquires the charging voltage command value Vᵢ and the pulse energy measured value Eᵢ of each pulse for one burst. The charging voltage command value Vᵢ is acquired from a history of a charging voltage set in the charger 12. The measured value Eᵢ of the pulse energy is acquired from the energy monitor 17.

In S23, the laser control processor 30 performs linear regression analysis using the charging voltage command value Vᵢ and the pulse energy measured value Eᵢ to obtain a regression formula for the pulse energy. A calculated value of the pulse energy obtained from the regression formula is denoted as Er. The regression formula is an example of a correlation between the charging voltage command value Vᵢ and the pulse energy in the present disclosure, and it may be a linear equation as shown below for example or any other higher-order equation.

$$Er = a \times {V}_{i} + b$$

In S24, the laser control processor 30 calculates a residual eᵢ of the measured value Eᵢ to the calculated value Er of the pulse energy calculated using the charging voltage command value Vᵢ and the regression formula for each pulse, as well as the standard deviation σ of the residual eᵢ. By using the residual eᵢ, it can be determined whether or not the measured value Eᵢ is outside the allowable range based on the calculated value Er. The residual eᵢ corresponds to a difference in the present disclosure and is calculated by an equation below.

$${e}_{i} = {E}_{i} - Er$$

In S25, the laser control processor 30 counts a pulse number n for which the residual eᵢ is outside a first allowable range, for example, the pulse number n that satisfies an expression below.

$${e}_{i} < - α \times σ$$

Here, α is a positive number that defines the first allowable range of the residual eᵢ, and is, for example, 3. The pulses to be counted may be only the pulses for which the residual eᵢ is a negative number, meaning that the measured value Eᵢ is smaller than the calculated value Er, and may be only the pulses for which an absolute value of the difference between the measured value Eᵢ and the calculated value Er is larger than or equal to α×σ.

In S26, the laser control processor 30 obtains a minimum value min(eᵢ) of the residual eᵢ.

In S27, the laser control processor 30 records the pulse number n for which the residual eᵢ is outside the first allowable range, and the minimum value min(eᵢ) of the residual eᵢ in the non-illustrated memory. The minimum value min(eᵢ) to be recorded can be either outside the first allowable range or within the first allowable range.

After S27, the laser control processor 30 returns the processing to S21 and repeats the same processing as above.

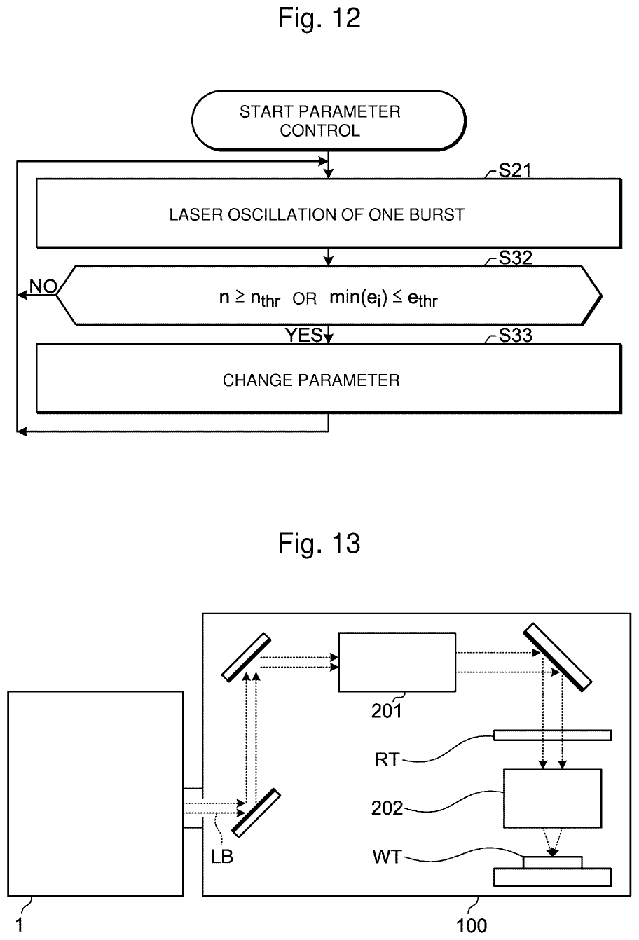

FIG. 12 is a flowchart of parameter control performed based on data acquired in the embodiment. The laser control processor 30 determines necessity of parameter update for each burst as follows and performs the parameter control.

In S21, the laser control processor 30 controls the excimer laser apparatus 1 so as to cause the laser oscillation of one burst. This processing is common to S21 illustrated in FIG. 11, and if the processing in FIG. 11 has been performed, S21 in FIG. 12 is omitted.

In S32, the laser control processor 30 determines whether or not the pulse number n for which the residual eᵢ is outside the first allowable range is larger than or equal to a threshold nₜₕᵣ, or whether or not the minimum value min(eᵢ) of the residual eᵢ is outside a second allowable range, that is, smaller than or equal to a threshold eₜₕᵣ. The threshold nₜₕᵣ may be a constant value or may be a value obtained by multiplying a constant ratio by the pulse number of one burst. The threshold eₜₕᵣ that defines the second allowable range is, for example, −4σ. Only when the minimum value min(eᵢ) of the residual eᵢ is a negative number, meaning that the measured value Eᵢ is smaller than the calculated value Er, it becomes smaller than or equal to the threshold eₜₕᵣ. If determination in S32 is NO, the laser control processor 30 returns the processing to S21. If the determination in S32 is YES, the laser control processor 30 advances the processing to S33.

In S33, the laser control processor 30 changes various parameters for controlling the excimer laser apparatus 1 to prevent the energy drop. Examples of various parameters are as follows.
The partial pressure of fluorine inside the chamber 10
The total pressure of the laser gas inside the chamber
The thresholds Vᵢmax and Vᵢmin of the charging voltage command value Vᵢ in controlling the total pressure of the laser gas
A frequency t_{freq} of a partial gas exchange, that is, the time from the last partial gas exchange to the next partial gas exchange, or an output pulse number from the last partial gas exchange to the next partial gas exchange
An exchange amount in one partial gas exchange

The exchange of the laser gas is not limited to the partial gas exchange, and may be a complete gas exchange. After S33, the laser control processor 30 returns the processing to S21.

### 2.2 Effect

(1) According to the embodiment, the excimer laser apparatus 1 includes the optical resonator, the chamber 10, the pulse power module 13, the charger 12, the energy monitor 17, and the laser control processor 30. The optical resonator is formed of the line narrowing module 14 and the output coupling mirror 15. The chamber 10 includes the pair of electrodes 11a and 11b, and is disposed in the optical path of the optical resonator. The pulse power module 13 applies a pulse voltage between the electrodes 11a and 11b. The charger 12 stores electric energy to be supplied to the pulse power module 13. The energy monitor 17 measures the pulse energy of the pulse laser beam LB output from the optical resonator. The laser control processor 30 acquires the charging voltage command value Vᵢ of the charger 12 and the measured value Eᵢ of the pulse energy for each of the pulses, obtains the regression formula indicating the correlation between the charging voltage command value Vᵢ and the pulse energy, and determines whether or not the measured value Eᵢ is outside the allowable range based on the calculated value Er of the pulse energy calculated from the charging voltage command value Vᵢ and the correlation.

Accordingly, by obtaining the correlation between the charging voltage command value Vᵢ and the pulse energy and determining whether or not the measured value Eᵢ of the pulse energy is outside the allowable range based on the calculated value Er of the pulse energy calculated from this correlation, it is possible to detect pulse energy abnormalities due to discharge abnormalities or the like. If the pulse energy abnormalities can be detected, it becomes possible to take measures such as changing parameters, thereby suppressing the degradation of the laser gas and the degradation of the electrodes 11a and 11b, and suppressing a decrease in exposure performance.

(2) According to the embodiment, the laser control processor 30 determines whether or not the measured value Eᵢ is smaller than the calculated value Er.

Accordingly, by determining whether or not the measured value Eᵢ is smaller, it is possible to detect an energy drop.

(3) According to the embodiment, the laser control processor 30 determines whether or not the measured value Eᵢ is outside the allowable range using the pulse number n of the pulse laser beam LB for which the absolute value of the residual eᵢ, that is the difference between the measured value Eᵢ and the calculated value Er, is larger than or equal to a threshold α×σ.

Accordingly, by using the pulse number n for which the absolute value of the residual eᵢ is larger than or equal to the threshold α×σ, it is possible to evaluate an occurrence frequency of the pulse energy abnormalities.

(4) According to the embodiment, the threshold α×σ is calculated using the standard deviation σ of the residual eᵢ.

Accordingly, by setting the threshold α×σ according to the standard deviation σ of the residual eᵢ, it is possible to detect an energy drop that exceeds the threshold α×σ corresponding to dispersion. Therefore, it is possible to avoid detecting an abnormality simply because the dispersion has increased.

(5) According to the embodiment, the laser control processor 30 determines whether or not the measured value Eᵢ is outside the allowable range using the minimum value min(eᵢ) of the residual eᵢ obtained by subtracting the calculated value Er from the measured value Eᵢ.

Accordingly, by using the minimum value min(eᵢ), it is possible to evaluate a degree of the energy drop.

(6) According to the embodiment, the laser control processor 30 controls the pulse power module 13 so that the burst oscillation in which the pulse laser beam LB is output at the predetermined repetition frequency, and the oscillation stop in which the output at the predetermined repetition frequency is stopped are alternately performed. The laser control processor 30 determines whether or not the measured value Eᵢ is outside the allowable range each time the burst oscillation is performed.

Accordingly, by making a determination each time the burst oscillation is performed, it is possible to detect abnormalities in an early stage. In addition, data can be retained for each burst oscillation.

(7) According to the embodiment, the laser control processor 30 changes parameters for controlling the excimer laser apparatus 1 when the measured value Eᵢ is outside the allowable range.

Accordingly, by changing parameters, it is possible to suppress the occurrence of the pulse energy abnormalities, to suppress the degradation of the laser gas and the degradation of the electrodes 11a and 11b, and to suppress the decrease in exposure performance.

(8) According to the embodiment, the parameter is the total pressure of the laser gas filled in the chamber 10.

Accordingly, by changing the total pressure of the laser gas, it is possible to improve the relationship between the pulse energy and the charging voltage command value V₁.

(9) According to the embodiment, the parameter is the partial pressure of fluorine contained in the laser gas filled in the chamber 10.

Accordingly, by changing the partial pressure of fluorine, it is possible to improve stability of the pulse energy.

(10) According to the embodiment, the parameter is the frequency t_{freq} of the exchange of the laser gas filled in the chamber 10.

Accordingly, by changing the frequency t_{freq} of the exchange of the laser gas, it is possible to adjust an amount of impurities contained in the laser gas and to suppress the pulse energy abnormalities.

In other respects, the embodiment is similar to the comparative example.

### 3. Others

### 3.1 Laser Control Processor 30

The laser control processor 30 may be physically configured as hardware to execute various kinds of processing included in the present disclosure. For example, the laser control processor 30 may be a computer including a memory that stores a control program defining the various kinds of processing and a processing device that executes the control program. The control program may be stored in one memory, or may be stored separately in a plurality of memories present at physically separate locations, and the various kinds of processing may be defined by a combination of the control programs. The processing device may be a general-purpose processing device such as a CPU or a special-purpose processing device such as a GPU.

Alternatively, the laser control processor 30 may be programmed as software to execute the various kinds of processing included in the present disclosure. For example, the laser control processor 30 may have functions to execute the various kinds of processing implemented in a dedicated device such as an ASIC or a programmable device such as a FPGA.

The various kinds of processing included in the present disclosure may be executed by one computer, one dedicated device, or one programmable device, or may be executed by cooperation of a plurality of computers, a plurality of dedicated devices, or a plurality of programmable devices present at physically separate locations. The various kinds of processing may be executed by a combination including at least any two of one or more computers, one or more dedicated devices, and one or more programmable devices.

### 3.2 Electronic Device Manufacturing Method

FIG. 13 illustrates a configuration of the exposure system. The exposure system includes the excimer laser apparatus 1 and the exposure apparatus 100. The excimer laser apparatus 1 is configured to output the pulse laser beam LB toward the exposure apparatus 100.

The exposure apparatus 100 includes an illumination optical system 201 and a projection optical system 202. The illumination optical system 201 illuminates a reticle pattern of a non-illustrated reticle disposed on a reticle stage RT with the pulse laser beam LB incident from the excimer laser apparatus 1. The pulse laser beam LB having transmitted through the reticle is imaged on a non-illustrated workpiece disposed on a workpiece table WT by reduced projection through the projection optical system 202. The workpiece is a photosensitive substrate such as a semiconductor wafer on which photoresist is applied.

The exposure apparatus 100 translates the reticle stage RT and the workpiece table WT in synchronization so that the workpiece is exposed to the pulse laser beam LB reflecting the reticle pattern. An electronic device can be manufactured through a plurality of processes after the reticle pattern is transferred onto the semiconductor wafer WF through the exposure process as described above.

### 3.3 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms unless otherwise stated. For example, terms such as “comprise”, “include”, “have”, and “contain” should not be interpreted to be exclusive of other structural elements. Further, indefinite articles “a/an” should be interpreted to mean “at least one” or “one or more.” Further, “at least one of A, B, and C” should be interpreted to mean any of A, B, C, A+B, A+C, B+C, and A+B+C. In addition, it should be interpreted to also include combinations of any thereof and any other than A, B, and C.

What is claimed is:

1. An excimer laser apparatus comprising:
an optical resonator;
a chamber that includes a pair of electrodes and is disposed in an optical path of the optical resonator;
a pulse power module configured to apply a pulse voltage between the electrodes;
a charger configured to store electric energy to be supplied to the pulse power module;
an energy monitor configured to measure pulse energy of a pulse laser beam output from the optical resonator; and
a processor configured to
acquire a charging voltage command value of the charger and a measured value of the pulse energy for each of a plurality of pulses,
obtain a correlation between the charging voltage command value and the pulse energy, and
determine whether or not the measured value is outside an allowable range based on a calculated value of the pulse energy calculated from the charging voltage command value and the correlation.

2. The excimer laser apparatus according to claim 1, wherein
the processor determines whether or not the measured value is smaller than the calculated value.

3. The excimer laser apparatus according to claim 1, wherein
the processor determines whether or not the measured value is outside the allowable range using a pulse number of the pulse laser beam for which an absolute value of a difference between the measured value and the calculated value is larger than or equal to a threshold.

4. The excimer laser apparatus according to claim 3, wherein
the threshold is calculated using a standard deviation of the difference.

5. The excimer laser apparatus according to claim 1, wherein
the processor determines whether or not the measured value is outside the allowable range using a minimum value of values obtained by subtracting the calculated value from the measured value.

6. The excimer laser apparatus according to claim 1, wherein
the processor
controls the pulse power module so that burst oscillation in which the pulse laser beam is output at a predetermined repetition frequency and an oscillation stop in which the output at the predetermined repetition frequency is stopped are alternately performed, and
determines whether or not the measured value is outside the allowable range each time the burst oscillation is performed.

7. The excimer laser apparatus according to claim 1, wherein
the processor changes parameters for controlling the excimer laser apparatus when the measured value is outside the allowable range.

8. The excimer laser apparatus according to claim 7, wherein
the parameter is a total pressure of a laser gas filled in the chamber.

9. The excimer laser apparatus according to claim 7, wherein
the parameter is a partial pressure of fluorine contained in a laser gas filled in the chamber.

10. The excimer laser apparatus according to claim 7, wherein
the parameter is an exchange frequency of a laser gas filled in the chamber.

11. An electronic device manufacturing method comprising:
generating a pulse laser beam with an excimer laser apparatus, the excimer laser apparatus including
an optical resonator,
a chamber that includes a pair of electrodes and is disposed in an optical path of the optical resonator,
a pulse power module configured to apply a pulse voltage between the electrodes,
a charger configured to store electric energy to be supplied to the pulse power module,
an energy monitor configured to measure pulse energy of the pulse laser beam output from the optical resonator, and
a processor configured to
acquire a charging voltage command value of the charger and a measured value of the pulse energy for each of a plurality of pulses,
obtain a correlation between the charging voltage command value and the pulse energy, and
determine whether or not the measured value is outside an allowable range based on a calculated value of the pulse energy calculated from the charging voltage command value and the correlation;
outputting the pulse laser beam to an exposure apparatus; and
exposing a photosensitive substrate to the pulse laser beam in the exposure apparatus to manufacture the electronic device.

12. The electronic device manufacturing method according to claim 11, wherein
the processor determines whether or not the measured value is smaller than the calculated value.

13. The electronic device manufacturing method according to claim 11, wherein
the processor determines whether or not the measured value is outside the allowable range using a pulse number of the pulse laser beam for which an absolute value of a difference between the measured value and the calculated value is larger than or equal to a threshold.

14. The electronic device manufacturing method according to claim 13, wherein
the threshold is calculated using a standard deviation of the difference.

15. The electronic device manufacturing method according to claim 11, wherein
the processor determines whether or not the measured value is outside the allowable range using a minimum value of values obtained by subtracting the calculated value from the measured value.

16. The electronic device manufacturing method according to claim 11, wherein
the processor
controls the pulse power module so that burst oscillation in which the pulse laser beam is output at a predetermined repetition frequency and an oscillation stop in which the output at the predetermined repetition frequency is stopped are alternately performed, and
determines whether or not the measured value is outside the allowable range each time the burst oscillation is performed.

17. The electronic device manufacturing method according to claim 11, wherein
the processor changes parameters for controlling the excimer laser apparatus when the measured value is outside the allowable range.

18. The electronic device manufacturing method according to claim 17, wherein
the parameter is a total pressure of a laser gas filled in the chamber.

19. The electronic device manufacturing method according to claim 17, wherein
the parameter is a partial pressure of fluorine contained in a laser gas filled in the chamber.

20. The electronic device manufacturing method according to claim 17, wherein
the parameter is an exchange frequency of a laser gas filled in the chamber.
